(19) United States
(12) Patent Application Publication
(10) Pub. No.: US 2007/0045674 A1
(43) Pub. Date: Mar. 1, 2007

(54) Semiconductor device and method of fabricating same

(75) Inventor: Taiki Komoda, Kanagawa (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/511,519

(22) Filed: Aug. 29, 2006

(30) Foreign Application Priority Data
Aug. 30, 2005 (JP) 2005-250359

(51) Int. Cl. H01L 31/112

(52) U.S. Cl. 257/270

(57) ABSTRACT

A semiconductor device includes: two MOSFETs each having a gate electrode formed on a substrate through a gate insulating film, a gate sidewall formed on both sides of the gate electrode, and a source/drain region formed in the substrate; a filled film filled between the adjacent gate sidewalls of the two MOSFETs; and a covering layer covering the gate electrodes and the gate sidewalls of the two MOSFETs, and the filled film to give each of channels formed between the source/drain regions, respectively, a strain.

### CROSS-REFERENCE TO RELATED APPLICATIONS

This application is based upon and claims the benefit of priority from prior Japanese Patent Application No. 2005-250359, filed Aug. 30, 2005, the entire contents of which are incorporated herein by reference.

### BACKGROUND OF THE INVENTION

The present invention relates to a semiconductor device and a method of fabricating the same, and more particularly to a structure, of a MOSFET, which gives a channel a strain, and a method of fabricating the MOSFET having such a structure.

A high throughput has been required for semiconductor devices with the advance of information communication apparatuses, and this requirement has been attained by the advance of a fine pattern technology such as a photolithography technology. In particular, in a silicon semiconductor, a processing size has entered a region of nanometers. Thus, in the present 90 nm node, a size of a gate electrode has already become 50 nm or less. A fine patterning size such as a minimum gate length is rate-determined by the wavelength in the photolithography technology. Thus, a technique for increasing a mobility becomes essential to the high speed operation in metal oxide semiconductor field effect transistors (MOSFETs) in and after the 45 nm node.

Then, a method is disclosed in which a silicon germanium layer is deposited on a substrate, and a silicon layer is epitaxially grown on the silicon germanium layer to strain a silicon crystal, thereby giving a portion intended to turn into a channel a strain, so that a mobility of an electron is increased to realize the high speed operation of a transistor. This method, for example, is described in Japanese Patent KOKAI No. 11-340337.

However, when a crystalline material is epitaxially grown on another crystalline material different in lattice constant from the former so that both the crystalline materials are made to lattice-match each other, a large strain appears in the crystals, and a dislocation is generated in the crystals. In addition thereto, a new fabricating system must be introduced into semiconductor fabricating processes due to introduction of the silicon germanium material which is not generally known in the semiconductor fabricating processes. As a result, the cost increases with the introduction of the new fabrication system. Thus, it is not easy to make this method fit for practical use. In addition, it is difficult to fabricate a complementary MOSFET (CMOSFET) or the like requiring both an N-channel MOSFET and a P-channel MOSFET by utilizing this method.

In addition, in a semiconductor device including an N-channel field effect transistor and a P-channel field effect transistor whose channel directions are parallel to a <100> axis, each of channel portions is given a strain, thereby allowing excellent drain current characteristics to be obtained in each of the N-channel field effect transistor and the P-channel field effect transistor. This semiconductor device, for example, is disclosed in Japanese Patent KOKAI No. 2004-87640.

However, any of conventional fabricating process data cannot be used since a silicon substrate is used whose crystal axis direction is different from that of the silicon substrate which is generally used. As a result, a stage has not yet been reached at which the semiconductor device capable of stably operating at a high processing speed is obtained.

### BRIEF SUMMARY OF THE INVENTION

A semiconductor device according to one embodiment of the present invention includes:

two MOSFETs each having a gate electrode formed on a substrate through a gate insulating film, a gate sidewall formed on both sides of the gate electrode, and a source/drain region formed in the substrate;

a filled film filled between the adjacent gate sidewalls of the two MOSFETs; and

a covering layer covering the gate electrodes and the gate sidewalls of the two MOSFETs, and the filled film to give each of channels formed between the source/drain regions, respectively, a strain.

A semiconductor device according to another embodiment of the present invention includes:

two MOSFETs of a first conductivity type each having a first gate electrode formed on a substrate through a first gate insulating film, a first gate sidewall formed on both sides of the first gate electrode, and a first source/drain region formed in the substrate;

two MOSFETs of a second conductivity type each having a second gate electrode formed on a substrate through a second gate insulating film, a second gate sidewall formed on both sides of the second gate electrode, and a second source/drain region formed in the substrate;

a filled film filled between the adjacent first gate sidewalls of the two MOSFETs of the first conductivity type;

a first covering layer covering the first gate electrodes, the first gate sidewalls, and the filled film to give each of first channels formed between the first source/drain regions, respectively, a strain; and

a second covering layer covering the second gate electrodes and the second gate sidewalls to give each of second channels formed between the second source/drain regions, respectively, a strain.

A method of fabricating a semiconductor device according to still another embodiment of the present invention includes:

forming two MOSFETs each having a gate electrode formed on a substrate through a gate insulating film, a gate sidewall formed on both sides of the gate electrode, and a source/drain region formed in the substrate;

forming a filled film between the adjacent gate sidewalls of the two MOSFETs; and

covering the gate electrodes and the gate sidewalls of the two MOSFETs, and the filled film with a covering layer for giving each of channels of the source/drain regions a strain.

### BRIEF DESCRIPTION OF THE DRAWINGS

FIGS. 1A to 1C are respectively cross sectional views showing a method of fabricating N-channel MOSFETs according to a first embodiment of the present invention in order;

FIGS. 2A to 2C are respectively cross sectional views showing a method of fabricating the N-channel MOSFETs according to the first embodiment of the present invention in order;

FIGS. 3A and 3B are cross sectional views showing a semiconductor device in a comparative example;

FIGS. 4A to 4C are respectively cross sectional views showing a method of fabricating a semiconductor device, in which N-channel MOSFETs and P-channel MOSFETs are formed on a substrate, according to a third embodiment of the present invention in order;

FIGS. 5A to 5C are respectively cross sectional views showing a method of fabricating the semiconductor device, in which the N-channel MOSFETs and the P-channel MOSFETs are formed on the substrate, according to the third embodiment of the present invention in order;

FIGS. 6A to 6C are respectively cross sectional views showing a method of fabricating the semiconductor device, in which the N-channel MOSFETs and the P-channel MOSFETs are formed on the substrate, according to the third embodiment of the present invention in order;

FIGS. 7A to 7C are respectively cross sectional views showing a method of fabricating a semiconductor device, in which N-channel MOSFETs and P-channel MOSFETs are formed on a substrate, according to a fifth embodiment of the present invention in order;

FIGS. 8A to 8C are respectively cross sectional views showing a method of fabricating the semiconductor device, in which the N-channel MOSFETs and the P-channel MOSFETs are formed on the substrate, according to the fifth embodiment of the present invention in order;

FIGS. 9A to 9C are respectively cross sectional views showing a method of fabricating the semiconductor device, in which the N-channel MOSFETs and the P-channel MOSFETs are formed on the substrate, according to the fifth embodiment of the present invention in order;

FIG. 10 is a cross sectional view showing a semiconductor device, in which each of gate sidewalls is thinned, according to a sixth embodiment of the present invention; and

FIG. 11 is a cross sectional view of a conceptual semiconductor device to example effects of the first to sixth embodiments of the present invention.

### DETAILED DESCRIPTION OF THE INVENTION

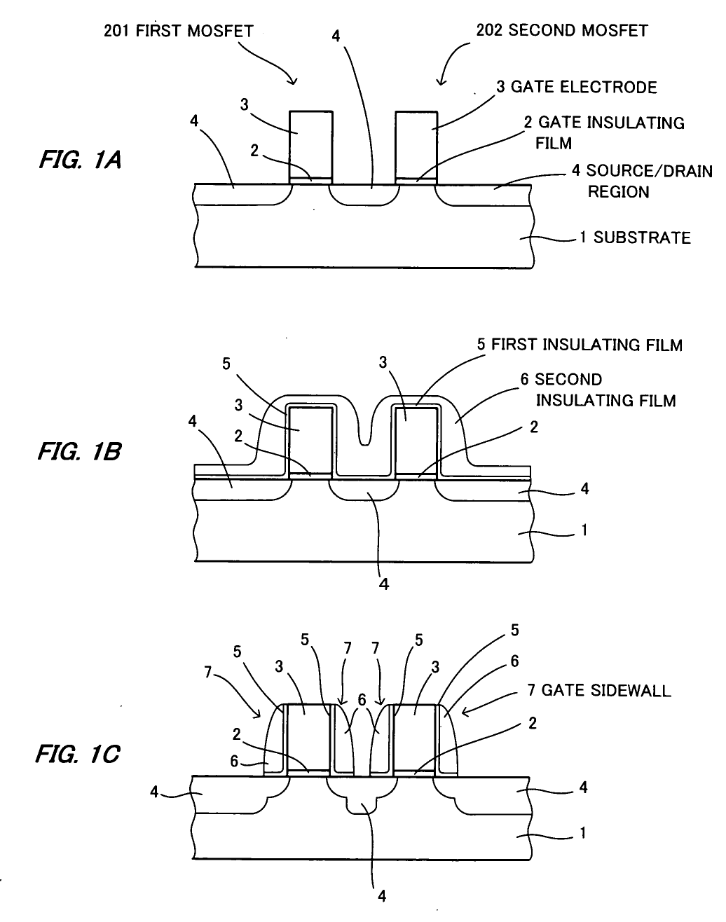

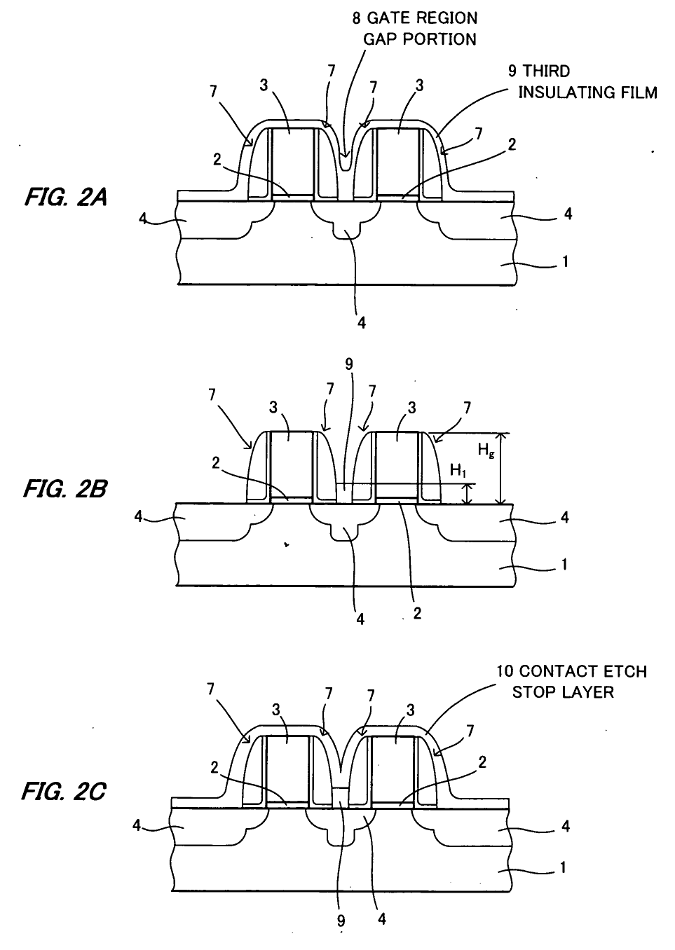

FIGS. 1A to 1C and FIGS. 2A to 2C are respectively cross sectional views showing a flow of processes for fabricating N-channel MOSFETs according to a first embodiment of the present invention in order. In the first embodiment, it is assumed that a plurality of N-channel MOSFETs are formed on a substrate, and of the plurality of N-channel MOSFETs, a first MOSFET 201 and a second MOSFET 202 are formed near each other, and also a gap having a predetermined size is defined between the first MOSFET 201 and the second MOSFET 202. The flow of the fabricating processes will now be shown in order with respect to a first N-channel MOSFET region and a second N-channel MOSFET region on this assumption.

As shown in FIG. 1A, a gate insulating film 2 such as a silicon oxide film is formed on a substrate 1 as a p-type silicon substrate, and a gate electrode 3 composed of a polysilicon is formed on the gate insulating film 2. The gate insulating film 2 and the gate electrode 3 are formed using the photo mask by utilizing a photolithography process and a reactive ion etching (RIE) technique.

An n-type impurity such as phosphorus or arsenic is diffused to form an extension region constituting a source/drain region 4. Here, for example, the gate insulating film 2, the gate electrode 3, and the extension region constituting the source/drain region 4 may be formed on a p-type well formed in an n-type silicon substrate used instead of the p-type silicon substrate.

Next, as shown in FIG. 1B, a first insulating film 5 such as a silicon oxide film is deposited on the gate insulating film 2, the gate electrode 3, and the extension region constituting the source/drain region 4, and a second insulating film 6 such as a silicon nitride film is deposited on the first insulating film 5.

Next, as shown in FIG. 1C, the second insulating film 6 is subjected to anisotropic etching using the first insulating film 5 as an etching stopper by utilizing the RIE technique or the like. After that, a part of the first insulating film 5 is removed, and a gate sidewall 7 including the first insulating film 5 and the second insulating film 6 is formed on both sides of the gate electrode 3. Ions are then implanted into the extension region using the gate sidewall 7 as a mask to form a deep source/drain region. As a result, the resulting deep source/drain region forms together with the above-mentioned extension region the source/drain region 4.

Next, as shown in FIG. 2A, a third insulating film 9 is deposited over the first MOSFET 201 and the second MOSFET 202. There is especially no limit to a material for the third insulating film 9. For example, a silicon oxide film, a silicon nitride film or the like may be used. In addition, any suitable film (for example, a film having a conductivity) other than any of the insulating films may also be used. However, it is feared that use of the film having a conductivity may increase a parasitic capacitance. From this reason, the insulating film is preferably used.

FIG. 2B shows a process for etching the third insulating film 9. The third insulating film 9 is removed through an etch back process by utilizing the RIE technique using a fluorine system gas such as CF₄. That is to say, the third insulating film 9 is in a state of being filled in a space defined between the adjacent gate sidewalls 7 of the first and second MOSFETs 201 and 202. Since the first and second MOSFETs 201 and 202 are close to each other, the third insulating film 9 is easy to remain in a gate region gap portion 8. As shown in the figure, when a height of the gate electrode 3 is H_{g}, a height, H₁, of the third insulating film 9 left in the gate region gap portion 8 after completion of the etch back is preferably not larger than H_{g}. The height, H₁, of the third insulating film 9 is set to a predetermined value so that an amount of strain which will be described later becomes a desirable state. Otherwise, the various kinds of process parameters are set in the semiconductor fabricating processes so that the height, H₁, of the third insulating film 9 becomes a predetermined value.

FIG. 2C shows a process for forming a contact etch stop layer 10 as a covering film which covers the gate electrodes 3 and the gate sidewalls 7 of the first and second MOSFETs 201 and 202, and the third insulating film 9. The contact etch stop layer 10 is formed in a state in which the third insulating film 9 is left with the predetermined height in the gate region gap portion 8 in the manner as described above. The contact etch stop layer 10 is deposited in the form of a silicon nitride film on the gate region gap portion 8, the gate electrodes 3 and the gate sidewalls 7 of a first N-channel MOSFET region and a second N-channel MOSFET region by a plasma enhanced chemical vapor deposition (CVD) system. The various kinds of film qualities can be set for the silicon nitride film in accordance with the running conditions of the plasma enhanced CVD system. Thus, in the processes for fabricating the N-channel MOSFETs, the film quality is set so as to give each of channels a tensile stress. For example, an SiₓN_{y} (where 0<x<1, and y=1−x) film can be set as the silicon nitride film by suitably setting a radio frequency (RF) power and the like of the plasma enhanced CVD system. Thus, the setting can be made so as to give each of the channels the tensile stress. In addition, in the process for fabricating the N-channel MOSFETs, even when an Si₃N₄ film is formed as a silicon nitride film by a CVD system, it is possible to form the contact etch stop layer 10 which gives each of the channels the tensile stress.

After completion of the above-mentioned fabricating processes, contact holes are formed on the source/drain regions 4 by utilizing a self align contact (SAC) forming method. That is to say, after an interlayer insulating film (not shown) such as a silicon oxide film is deposited by utilizing the CVD method or the like, the interlayer insulating film is subjected to dry etching using the contact etch stop layer 10 as an etch stop by using a mask pattern for the contact holes, thereby forming an SAC structure.

According to the first embodiment of the present invention, the following effects are obtained.

(1) In the N-channel MOSFETs, the contact etch stop layer 10 having the tensile stress is formed on the gate electrodes 3 and the gate sidewalls 7. Thus, each of the channels formed in portions under the gate regions, respectively, is given the strain due to the tensile stress through the gate regions and their peripheral structures. As a result, the degenerated band structure of the silicon crystal is broken and energy levels are split. The change in band structure results in that an electron mobility is increased due to a decrease in carrier scattering by a lattice vibration, and reduction in effective mass. Although depending on the setting of the tensile stress, for each of the channels, in the contact etch stop layer 10, the electron mobility can be substantially doubled.

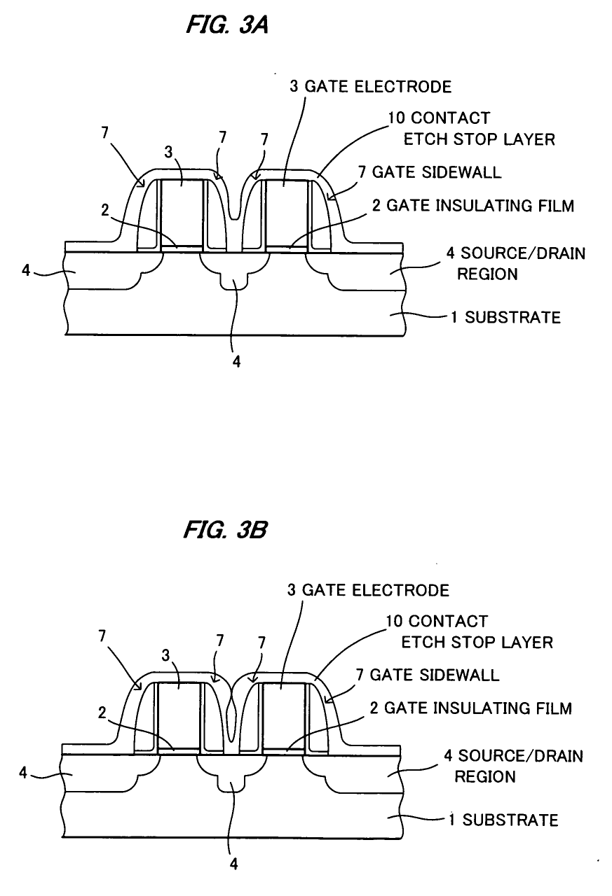

(2) In the first embodiment, as shown in FIG. 2C, the third insulating film 9 is left with the predetermined height in the gate region gap portion 8. Hence, even when the contact etch stop layer 10 having the tensile stress is formed on the third insulating film 9 thus left, in the gate region gap portion 8, the contact etch stop layer 10 is formed on the gate sidewalls 7 especially without being thinned or pinched off. As a result, the sufficient tensile stress is generated. For comparison with the first embodiment of the present invention, FIGS. 3A, and 3B show a state in which the contact etch stop layer 10 is formed without leaving the third insulating film 9 in the gate region gap portion 8. In the case of this comparative example, a portion of the contact etch stop layer 10 becomes thin (FIG. 3A) or pinched off (FIG. 3B) which is formed on the gate sidewall 7 especially in the gate region gap portion 8. As a result, no sufficient tensile stress is generated for each of the channels. On the other hand, the stress in each of the channels is induced by applying a film stress from an intermediate portion to an upper portion of the gate sidewall 7. As a result, it is possible to disregard an effect of degradation of the stress resulting from that the material is filled in the gate region gap portion 8. From this fact, the electron mobility can be stably and sufficiently increased due to the strain effect in each of the channels stated in the paragraph (1).

(3) Therefore, even under the future conditions in which it is difficult to enhance the performance by the scaling, this embodiment has the large effect in the semiconductor device which has a high processing speed and a large drive current, especially, in the N-channel MOSFET because the electron mobility can be increased.

A second embodiment of the present invention relates to P-channel MOSFETs, and only respects different from the first embodiment will be described hereinafter. Since other respects are merely differences between the normal P-channel MOSFET fabricating processes and the normal N-channel MOSFET fabricating processes, a description thereof is omitted here for the sake of simplicity.

In the processes for fabricating P-channel MOSFETs, an n-type silicon substrate is used instead of the p-type silicon substrate 1 shown in FIGS. 1A to 1C and FIGS. 2A to 2C. Otherwise, for example, the gate insulating film 2, the gate electrode 3, and the source/drain region 4 may be formed on an n-type well formed in a p-type silicon substrate instead of using the n-type silicon substrate. The processes for fabricating P-channel MOSFETs are the same as those shown in FIGS. 1A to 1C and FIGS. 2A to 2C.

As shown in FIG. 2C, the contact etch stop layer 10 is deposited in the form of a silicon nitride film on the gate region gap portion 8, the gate electrodes 3 and the gate sidewalls 7 by the plasma enhanced CVD system. The various kinds of film qualities can be set for the silicon nitride film in accordance with the running conditions of the plasma enhanced CVD system. Thus, in the processes for fabricating the P-channel MOSFETs, the film quantity is set so as to give each of the channels a compressive stress. For example, the SiₓN_{y} (where 0<x<1, and y=1−x) film can be set as the silicon nitride film by suitably setting the RF power and the like of the plasma enhanced CVD system. Thus, the setting can be made so as to give each of the channels the compressive stress.

According to the second embodiment of the present invention, the following effects are obtained.

(1) In the P-channel MOSFETs, the contact etch stop layer 10 is formed which gives each of the channels the compressive stress. Thus, each of the channels formed in the portions under the gate regions is given the strain due to the compressive stress through the gate regions and their peripheral structures. As a result, the degenerated band structure of the silicon crystal is broken and energy levels are split. The change in band structure results in that a hole mobility is increased due to a decrease in carrier scattering by the lattice vibration, and reduction in effective mass. Although depending on the setting of the compressive stress, for each of the channels, in the contact etch stop layer 10, the hole mobility can be substantially increased up to about 1.5 times as large as before.

(2) The third insulating film 9 is left with the predetermined height in the gate region gap portion 8 similarly to the description of the effects of the first embodiment. Hence, even when the contact etch stop layer 10 which gives each of the channels the tensile stress is formed on the third insulating film 9 thus left, in the gate region gap portion 8, the contact etch stop layer 10 is especially formed on the gate sidewall 7 without being thinned or pinched off. As a result, the sufficient compressive stress is generated. In addition, the stress in each of the channels is induced by applying the film stress from the intermediate portion to the upper portion of the gate sidewall 7. As a result, it is possible to disregard the effect of the degradation in the stress resulting from that the material is filled in the gate region gap portion 8. From this fact, the hole mobility can be stably and sufficiently increased due to the strain effect in each of the channels stated in the paragraph (1).

(3) Therefore, even under the future conditions in which it is difficult to enhance the performance by the scaling, this embodiment has the large effect in the semiconductor device which has the high processing speed and the large drive current, especially, in the P-channel MOSFETs because the hole mobility can be increases.

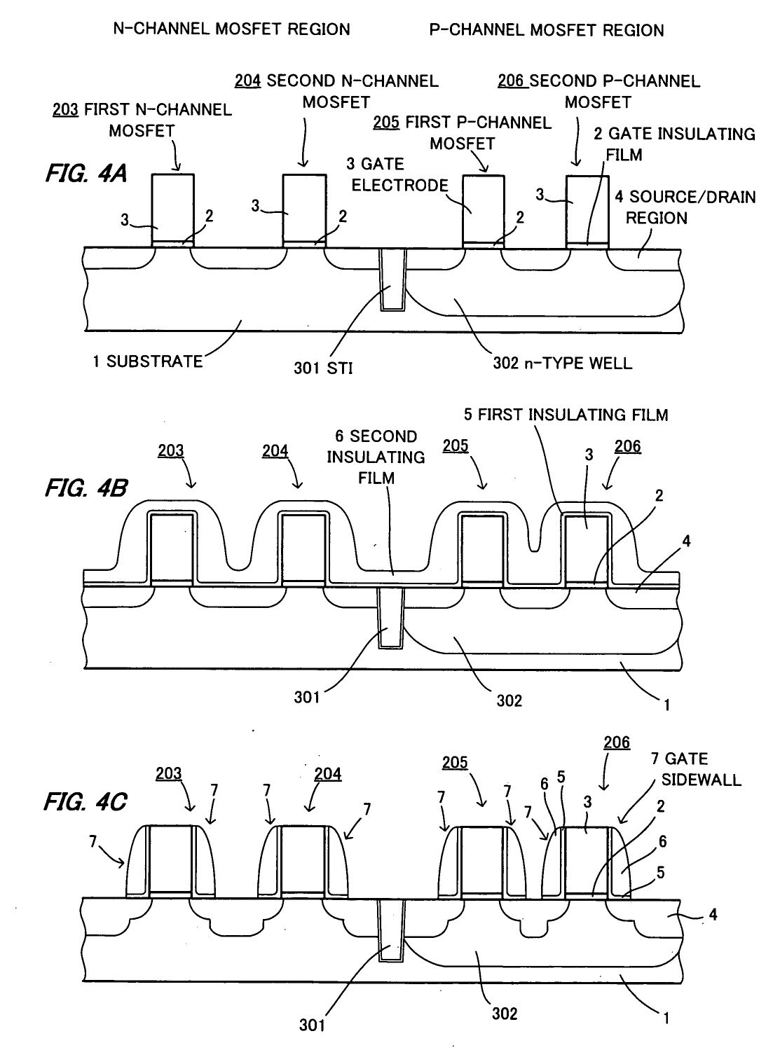

FIGS. 4A to 4C, FIGS. 5A to 5C, and FIGS. 6A to 6C show a flow of processes for fabricating a semiconductor device, in which N-channel MOSFETs and P-channel MOSFETs are formed on a substrate 1, according to a third embodiment of the present invention in order.

In this embodiment, it is assumed that a plurality of N-channel MOSFETs and a plurality of P-channel MOSFETs are formed on the substrate 1, and a first P-channel MOSFET 205 and a second P-channel MOSFET 206 are close to each other, and also a gap having a predetermined size is defined between the first P-channel MOSFET 205 and the second P-channel MOSFET 206. The flow of the fabricating processes will now be shown in order with respect to the left-hand side N-channel MOSFETs and the right-hand side P-channel MOSFETs in FIGS. 4A to 4C, FIGS. 5A to 5C, and FIGS. 6A to 6C on this assumption.

An N-channel MOSFET region shown in the left-hand side of FIG. 4A, and a P-channel MOSFET region shown in the right-hand side of FIG. 4A in the substrate 1 as a p-type silicon substrate are isolated from each other by a shallow trench isolation (STI) 301. An n-type well 302 is formed in the P-channel MOSFET region. For example, an n-type silicon substrate having a p-type well for the N-channel MOSFET region may be used instead of the p-type silicon substrate. A gate insulating film 2 such as a silicon oxide film is formed on the substrate 1, and a gate electrode 3 composed of a polysilicon is formed on the gate insulating film 2. The gate insulating film 2 and the gate electrode 3 are formed by using the photo mask by utilizing the photolithography process and the RIE technique.

An n-type impurity such as phosphorus or arsenic is diffused into an unmasked region with a region other than the N-channel MOSFET region being masked by the photo mask to form an extension region, constituting a source/drain region 4, of the N-channel MOSFET region.

In addition, a p-type impurity such as boron is diffused into an unmasked region with a region other than the P-channel MOSFET region being masked by the photo mask to form an extension region, constituting a source/drain region 4, of the P-channel MOSFET region.

Next, as shown in FIG. 4B, a first insulating film 5 such as a silicon oxide film is deposited on the gate insulating films 2, the gate electrodes 3, and the extension regions constituting the respective source/drain regions 4, and a second insulating film 6 such as a silicon nitride film is deposited on the first insulating film 5.

Next, as shown in FIG. 4C, the second insulating film 6 is subjected to the anisotropic etching using the first insulating film 5 as an etching stopper by utilizing the RIE technique or the like. After that, a part of the first insulating film 5 is removed, and a gate sidewall 7 including the first insulating film 5 and the second insulating film 6 is formed on both sides of the gate electrode 3. Ions are then implanted into the extension regions constituting the respective source/drain regions 4 using the gate sidewalls 7 as a mask to form deep source/drain regions. As a result, the resulting deep source/drain regions form together with the above-mentioned extension regions the source/drain regions 4, respectively.

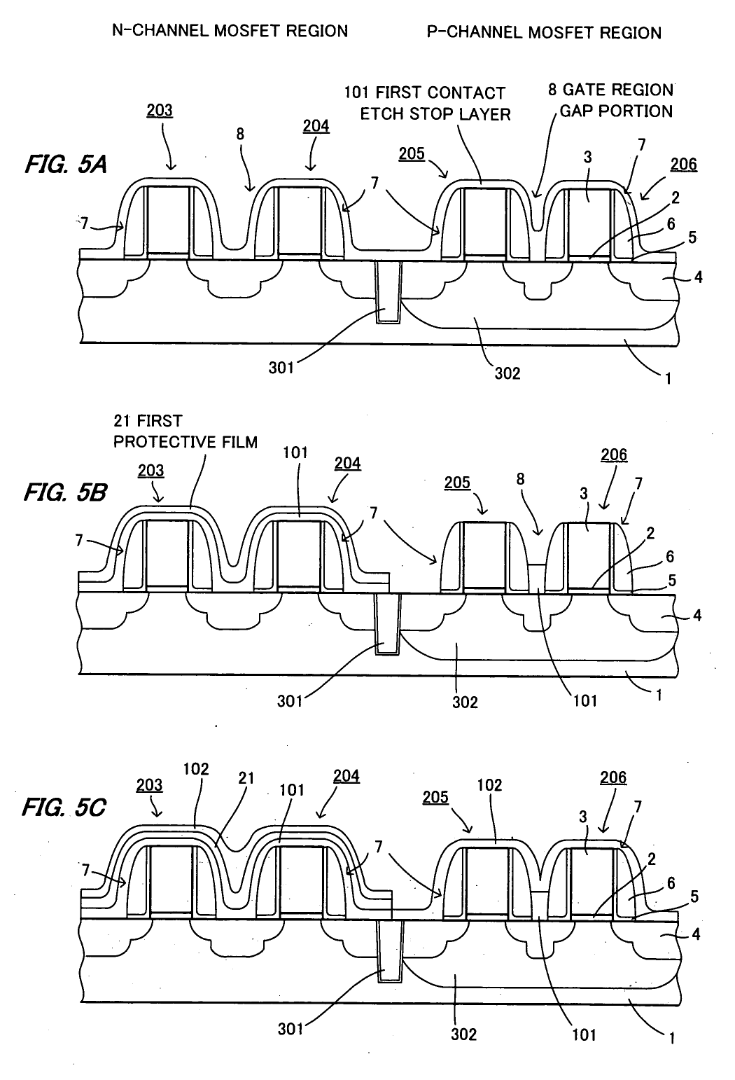

Next, as shown in FIG. 5A, a first contact etch stop layer 101 is deposited over the N-channel MOSFETs and the P-channel MOSFETs. The first contact stop layer 101 is a covering film which covers the gate electrodes 3 and the gate sidewalls 7. In this process, the first contact etch stop layer 101 is deposited which gives each of channels of the N-channel MOSFET region a tensile stress. Also, the first contact etch stop layer 101 is deposited in the form of the silicon nitride film on the gate region gap portions 8, the gate electrodes 3 and the gate sidewalls 7 by the plasma enhanced CVD system. The various kinds of film quantities can be set for the silicon nitride film in accordance with the running conditions of the plasma enhanced CVD system. Thus, in this process, in order to give each of the channels of the N-channel MOSFETs the tensile stress, the film quantity is set such that the silicon nitride film has the tensile stress. For example, the SiₓN_{y} (where 0<x<1, and y=1−x) film can be set as the silicon nitride film by suitably setting the RF power and the like of the plasma enhanced CVD system. Thus, the setting can be made such that the SiₓN_{y} film has the tensile stress. In addition, in this process, even when the Si₃N₄ film is formed as the silicon nitride film by the CVD system, it is possible to form the contact etch stop layer 10 which gives each of the channels of the N-channel MOSFET region the tensile stress.

FIG. 5B shows a process for etching the first contact etch stop layer 101. The first contact etch stop layer 101 in the P-channel MOSFET region is removed through the etch back process with the N-channel MOSFET region being masked by a first protective film 21 by, for example, utilizing the RIE technique. That is to say, the first contact etch stop layer 101 becomes a state of being filled in the gate region gap portion 8 defined between the adjacent gate sidewalls 7 of the first P-channel MOSFET 205 and the second P-channel MOSFET 206. Similarly to the description of the first embodiment, the height, H₁, of the first contact etch stop layer 101 is set to the predetermined value so that an amount of strain which will be described later becomes the desirable state. Otherwise, the various kinds of process parameters are set in the semiconductor fabricating processes so that the height, H₁, of the first contact etch stop layer 101 becomes the predetermined value.

Next, as shown in FIG. 5C, a second contact etch stop layer 102 is deposited over the N-channel MOSFET region and the P-channel MOSFET region. The second contact etch stop layer 102 is a covering film which covers the gate electrodes 3, the gate sidewalls 7, and the first contact etch stop layer 101 in the P-channel MOSFET region. In this process, in order to give each of channels of the P-channel MOSFET region a strain, the second contact etch stop layer 102 is deposited which gives each of the channels of the P-channel MOSFET region the compressive stress. Also, the second contact etch stop layer 102 is deposited in the form of the silicon nitride film on the gate region gap portions 8, the gate electrodes 3 and the gate sidewalls 7. The various kinds of film quantities can be set for the silicon nitride film in accordance with the running conditions of the plasma enhanced CVD system. Thus, in this process, the film quantity is set so as to give each of channels of the P-channel MOSFETs the compressive stress. For example, the SiₓN_{y} (where 0<x<1, and y=1−x) film can be set as the silicon nitride film by suitably setting the RF power and the like of the plasma enhanced CVD system. Thus, the setting can be made so as to give each of the channels the compressive stress.

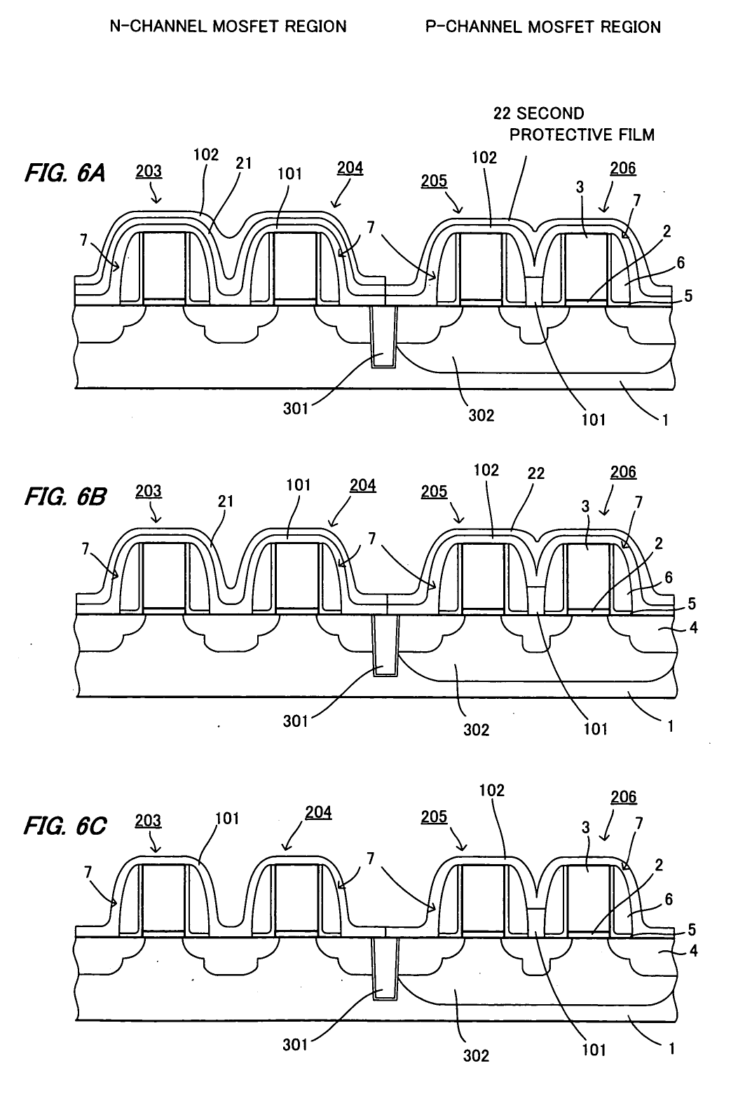

Next, as shown in FIGS. 6A to 6C, a second protective film 22 is formed over the P-channel MOSFET region as preparation for removing the second contact etch stop layer 102 formed over the N-channel MOSFET region. Next, the second contact etch stop layer 102 formed over the N-channel MOSFET is removed by utilizing the suitable etching method. Finally, the first protective film 21 and the second protective film 22 are peeled off. Here, a space defined between the first N-channel MOSFET 203 and the second N-channel MOSFET 204 is wider than that defined between the first P-channel MOSFET 205 and the second P-channel MOSFET 206. Thus, even when no insulating film having a predetermined height is filled in the gate region gap portion 8, the first contact etch stop layer 101 formed on the gate sidewall 7 is prevented from being thinned.

After completion of the above-mentioned fabricating processes, contact holes are formed on the source/drain regions 4 by utilizing the SAC forming method. That is to say, after an interlayer insulating film (not shown) such as a silicon oxide film is deposited by utilizing the CVD method or the like, the interlayer insulating film is subjected to the dry etching using the first contact etch stop layer 101 and the second contact etch stop layer 101 as an etch stop by using a mask pattern for the contact holes, thereby forming the SAC structure.

In the processes for fabricating the semiconductor device according to this embodiment which has been described above, the first contact etch stop layer 101 deposited in the process shown in FIG. 5A is identical to the first contact etch stop layer 101 left in the gate region gap portion 8 in the etch back process shown in FIG. 5B. However, even when an insulating film which is left in the gate region gap portion 8 in the etch back process shown in FIG. 5B is made of a material different from that of the first contact etch stop layer 101 in another process, the structure can be obtained which has the equal effects.

The third embodiment of the present invention has the following effects by addition of a few processes in addition to obtaining the same effects as those of the first and second embodiments in both the N-channel MOSFET region and the P-channel MOSFET region. That is to say, the formation of the first contact etch stop layer 101 and the second contact etch stop layer 102 which give each of the channels of the first and second N-channel MOSFETs 203 and 204 and each of the channels of the first and second P-channel MOSFETs 205 and 206 the tensile stress and the compressive stress, respectively, makes it possible to increase the drive current of both each of the first and second N-channel MOSFETs 203 and 204 and each of the first and second P-channel MOSFETs 205 and 206. Therefore, even under the future conditions in which it is difficult to enhance the performance by the scaling, according to this embodiment of the present invention, it is possible to increase the drive current in the semiconductor device having the N-channel MOSFET region and the P-channel MOSFET region on the substrate.

A fourth embodiment of the present invention is such that the contact etch stop layer is left in the gate region gap portion 8 of the N-channel MOSFET region instead of that of the P-channel MOSFET region. A space defined between the first P-channel MOSFET 205 and the second P-channel MOSFET 206 is wider than that defined between the first N-channel MOSFET 203 and the second N-channel MOSFET 204. Thus, even when no insulating film having a predetermined height is filled in the gate region gap portion 8, the first contact etch stop layer 101 formed on the gate sidewall 7 is prevented from being thinned. Thus, only respects different from the third embodiment will now be described. Also, since other respects are merely differences between the normal P-channel MOSFET fabricating processes and the normal N-channel MOSFET fabricating processes, a description thereof is omitted here for the sake of simplicity.

In the process shown in FIG. 5A, the first contact etch stop layer 101 is deposited which gives each of the channels of the P-channel MOSFET region the compressive stress. The first contact etch stop layer 101 is the covering film which covers the gate electrodes 3 and the gate sidewalls 7. The first contact etch stop layer 101 is deposited in the form of the silicon nitride film on the gate region gap portions 8, the gate electrodes 3 and the gate sidewalls 7 by the plasma enhanced CVD system. The various kinds of film qualities can be set for the silicon nitride film in accordance with the running conditions of the plasma enhanced CVD system. Thus, the film quality is set so as to give each of the channels of the P-channel MOSFETs the compressive stress. For example, the SiₓN_{y} (where 0<x<1, and y=1−x) film can be set as the silicon nitride film by suitably setting the RF power and the like of the plasma enhanced CVD system. Thus, the setting can be made so as to give each of the channels of the P-channel MOSFET region the compressive stress.

In the process shown in FIG. 5B, the etching process is carried out such that the first contact etch stop layer 101 is left in the gate region gap portion 8 defined between the first N-channel MOSFET 203 and the second N-channel MOSFET 204 of the N-channel MOSFET region with the P-channel MOSFET region being masked.

In the process shown in FIG. 5C, the second contact etch stop layer 102 is deposited over the N-channel MOSFET region and the P-channel MOSFET region. The second contact etch stop layer 102 is the covering film which covers the gate electrodes 3, the gate sidewalls 7, and the first contact etch stop layer 101 in the N-channel MOSFET region. In this process, in order to give each of channels of the N-channel MOSFET region a strain, the second contact etch stop layer 102 is deposited which gives each of the channels of the N-channel MOSFET region the tensile stress. Also, the second contact etch stop layer 102 is deposited in the form of the silicon nitride film on the gate region gap portions 8, the gate electrodes 3 and the gate sidewalls 7 by the plasma enhanced CVD system. The various kinds of film quantities can be set for the silicon nitride film in accordance with the running conditions of the plasma enhanced CVD system. Thus, in this process, the film quantity is set so as to give each of channels of the first and second N-channel MOSFETs 203 and 204 the tensile stress. For example, the SiₓN_{y} (where 0<x<1, and y=1−x) film can be set as the silicon nitride film by suitably setting the RF power and the like of the plasma enhanced CVD system. Thus, the setting can be made so as to give each of the channels of the N-channel MOSFET region the tensile stress. In addition, in this process, even when the Si₃N₄ film is formed as the silicon nitride film by the CVD system, it is possible to form the second contact etch stop layer 102 which gives each of the channels of the first and second N-channel MOSFETs 203 and 204 the tensile stress.

Next, as shown in FIGS. 6A to 6C, the protective film forming process and the peeling process are carried out similarly to those in the third embodiment. After completion of these fabricating processes, the SAC structure is formed.

The fourth embodiment of the present invention has the following effects by addition of a few processes in addition to obtaining the same effects as those of the first and second embodiments in both the N-channel MOSFET region and the P-channel MOSFET region. That is to say, the formation of the first contact etch stop layer 101 and the second contact etch stop layer 102 which give each of the channels of the first and second N-channel MOSFETs 203 and 204 and each of the channels of the first and second P-channel MOSFETs 205 and 206 the tensile stress and the compressive stress, respectively, makes it possible to increase the drive current of both each of the first and second N-channel MOSFETs 203 and 204 and each of the first and second P-channel MOSFETs 205 and 206.

Therefore, even under the future conditions in which it is difficult to enhance the performance by the scaling, according to this embodiment of the present invention, it is possible to increase the large drive current in the semiconductor device having the N-channel MOSFET region and the P-channel MOSFET region on the substrate.

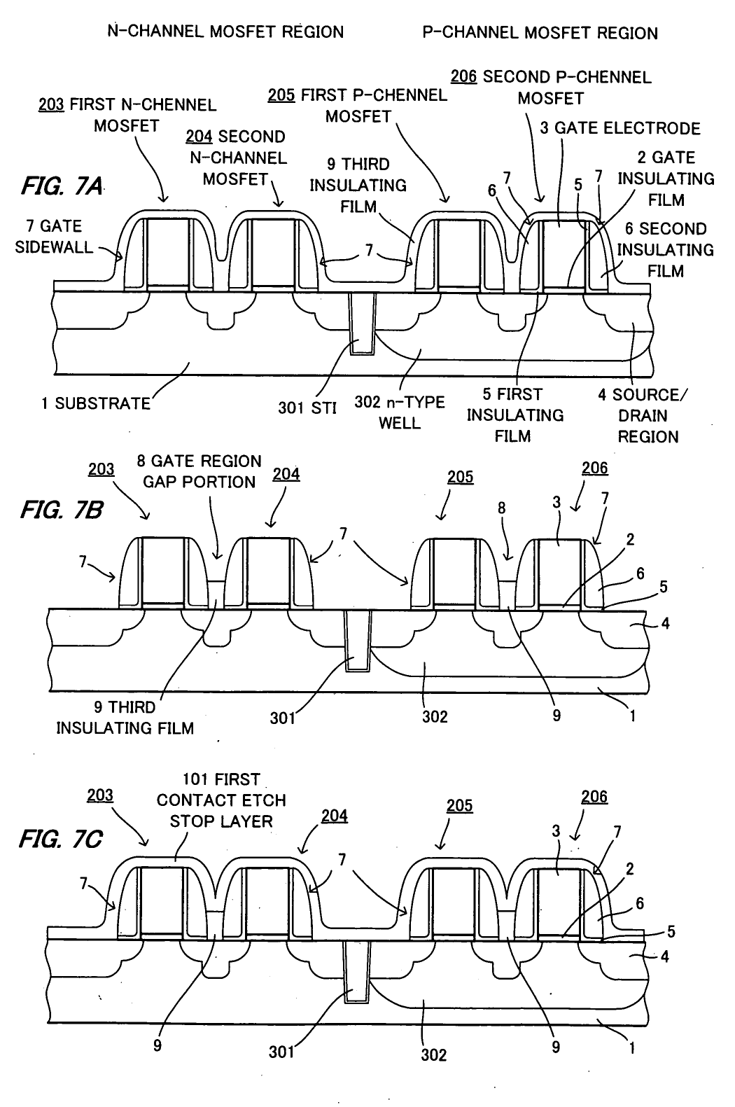

FIGS. 7A to 7C, FIGS. 8A to 8C and FIGS. 9A to 9C show a flow of processes for fabricating a semiconductor device, in which N-channel MOSFETs and P-channel MOSFETs are formed on a substrate, according to a fifth embodiment of the present invention in order.

In this embodiment, it is assumed that a plurality of N-channel MOSFETs and a plurality of P-channel MOSFETs are formed on a substrate 1, and a first N-channel MOSFET 203 and a second N-channel MOSFET 204 are close to each other in a region having the plurality of N-channel MOSFETs formed therein, and a first P-channel MOSFET 205 and a second P-channel MOSFET 206 are also close to each other in a region having the plurality of P-channel MOSFETs formed therein, and also gaps having respective predetermined sizes are defined between the first N-channel MOSFET 203 and the second N-channel MOSFET 204, and between the first P-channel MOSFET 205 and the second P-channel MOSFET 206, respectively. The flow of the fabricating processes will now be shown in order with respect to the left-hand side first and second N-channel MOSFETs 203 and 204, and the right-hand side first and second P-channel MOSFETs 204 and 205 shown in FIGS. 7A to 7C, FIGS. 8A to 8C and FIGS. 9A to 9C on this assumption. Here, since the fabricating processes until the process shown in FIG. 4C described in the third embodiment are the almost same as those of the fifth embodiment, a description and illustration thereof are omitted here for the sake of simplicity.

As shown in FIG. 7A, a third insulating film 9 is deposited over an N-channel MOSFET region and a P-channel MOSFET region. There is especially no limit to a material for the third insulating film 9. For example, a silicon oxide film, a silicon nitride film or the like may be used. In addition, any suitable film (for example, a film having a conductivity) other than any of the insulating films may also be used. However, it is feared that use of the film having a conductivity may increase a parasitic capacitance. From this reason, the insulating film is preferably used.

FIG. 7B shows a process for etching the third insulating film 9. The third insulating film 9 is removed through the etch back process by utilizing the RIE technique using the fluorine system gas such as CF₄. That is to say, the third insulating film 9 is in a state of being filled in a space (a gate region gap portion 8) defined between adjacent gate sidewalls of the first and second N-channel MOSFETs 203 and 204, and in a space (a gate region gap portion 8) defined between adjacent gate sidewalls of the first and second P-channel MOSFETs 205 and 206. Similarly to the description of the first embodiment, the height, H₁, of the third insulating film 9 is set to the predetermined value so that an amount of strain which will be described later becomes the desirable state. Otherwise, the various kinds of process parameters are set in the semiconductor fabricating processes so that the height, H₁, of the third insulating film 9 becomes the predetermined value.

Next, as shown in FIG. 7C, a first contact etch stop layer 101 is deposited over the first and second N-channel MOSFETs 203 and 204, and the first and second P-channel MOSFETs 205 and 206. The first contact etch stop layer 101 is a covering film which covers the gate electrodes 3, the gate sidewalls 7, and the first insulating film 9. In this process, the first contact etch stop layer 101 is deposited which gives each of the channels of the N-channel MOSFET region a tensile stress. The first contact etch stop layer 101 is deposited in the form of the silicon nitride film on the gate region gap portions 8, the gate electrodes 3 and the gate sidewalls 7 by the plasma enhanced CVD system. The various kinds of film qualities can be set for the silicon nitride film in accordance with the running conditions of the plasma enhanced CVD system. Thus, the film quality is set so as to give each of the channels of the first and second N-channel MOSFETs 203 and 204. For example, the SiₓN_{y} (where 0<x<1, and y=1−x) film can be set as the silicon nitride film by suitably setting the RF power and the like of the plasma enhanced CVD system. Thus, the setting can be made so as to give each of the channels of the N-channel MOSFET region the tensile stress. In addition, in this process, even when the Si₃N₄ film is formed as the silicon nitride film by the CVD system, it is possible to form the first contact etch stop layer 101 which gives each of the channels of the first and second N-channel MOSFETs 203 and 204 the tensile stress.

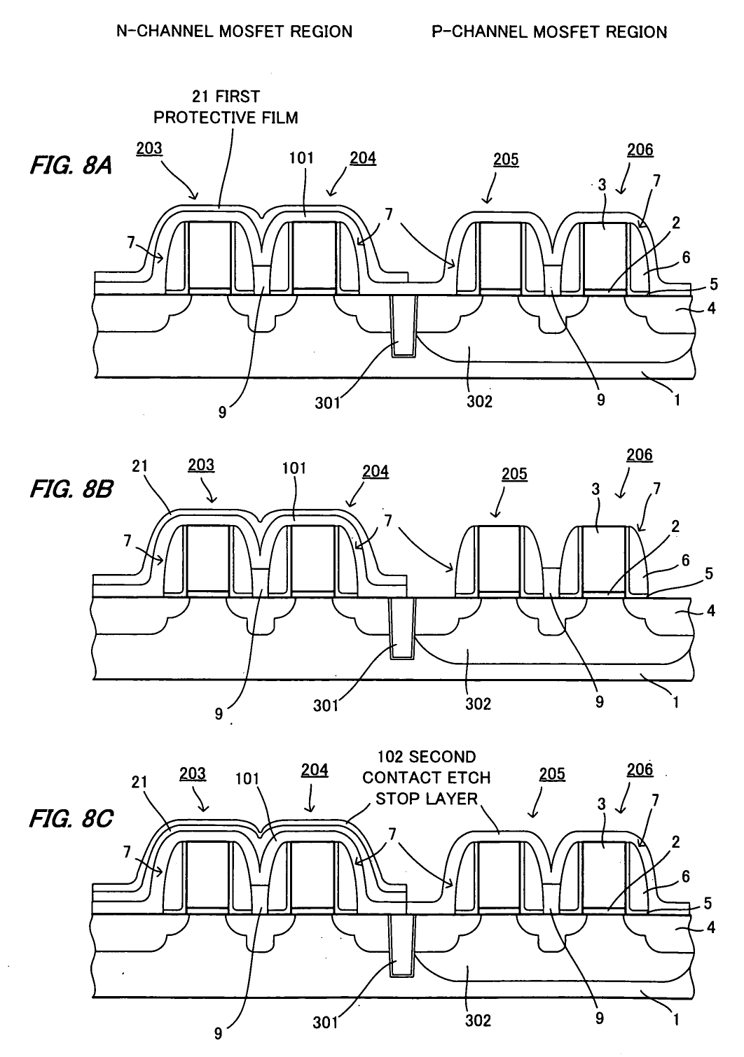

FIG. 8A shows a state in which the N-channel MOSFET region is masked by a first protective film 21 as preparation for removing the first contact etch stop layer 101 formed over the P-channel MOSFET region.

FIG. 8B shows a process for etching the first contact etch stop layer 101. The first contact etch stop layer 101 in the P-channel MOSFET region is removed through the etch back process by, for example, utilizing the RIE technique.

Next, as shown in FIG. 8C, a second contact etch stop layer 102 is deposited over the N-channel MOSFET region and the P-channel MOSFET region. The second contact etch stop layer 102 is a covering film which covers the gate electrodes 3, the gate sidewalls 7, and the first insulating film 9 in the P-channel MOSFET region. In this process, in order to give each of channels of the P-channel MOSFET region a strain, the second contact etch stop layer 102 is deposited which gives each of the channels of the P-channel MOSFET region the compressive stress. Also, the second contact etch stop layer 102 is deposited in the form of the silicon nitride film on the gate region gap portions 8, the gate electrodes 3 and the gate sidewalls 7 by the plasma enhanced CVD system. The various kinds of film quantities can be set for the silicon nitride film in accordance with the running conditions of the plasma enhanced CVD system. Thus, in this process, the film quantity is set so as to give each of channels of the first and second P-channel MOSFETs 205 and 206 a compressive stress. For example, the SiₓN_{y} (where 0<x<1, and y=1−x) film can be set as the silicon nitride film by suitably setting the RF power and the like of the plasma enhanced CVD system. Thus, the setting can be made so as to give each of the channels of the P-channel MOSFET region the compressive stress.

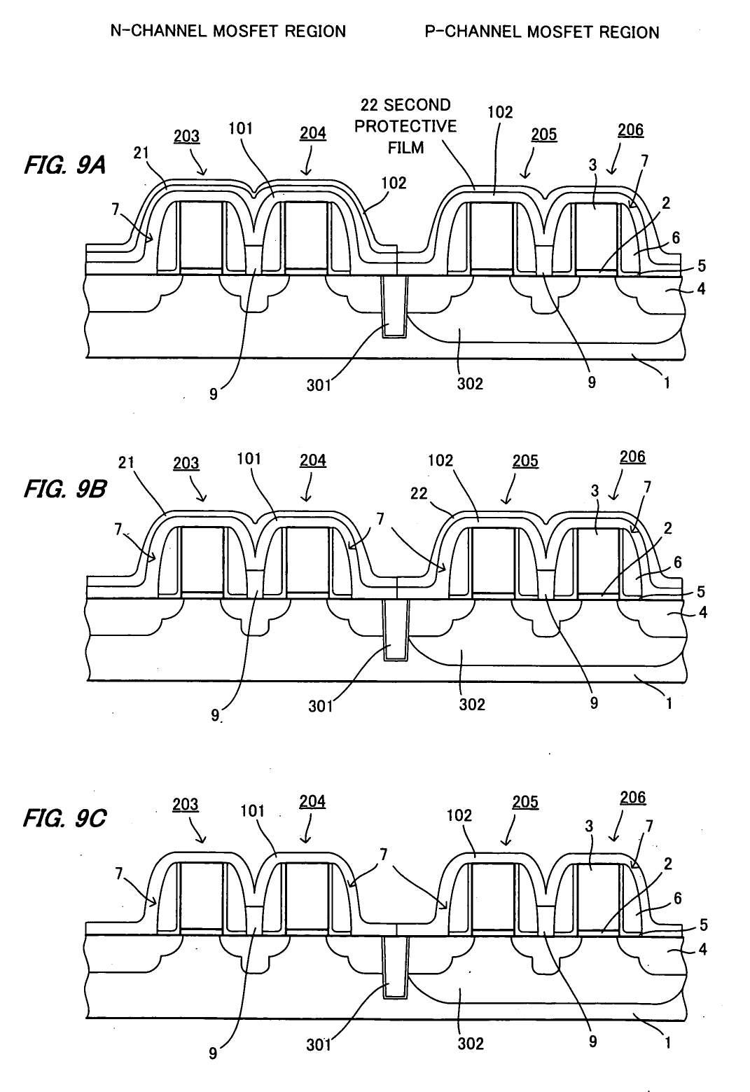

Next, as shown in FIGS. 9A to 9C, a second protective film 22 is formed over the P-channel MOSFET region as preparation for removing the second contact etch stop layer 102 formed over the N-channel MOSFET region. Next, the second contact etch stop layer 102 formed over the N-channel MOSFET region is removed by utilizing the suitable etching method. Finally, the first protective film 21 and the second protective film 22 are peeled off.

After completion of the above-mentioned fabricating processes, contact holes are formed on the source/drain regions 4 by utilizing the SAC forming method. That is to say, after an interlayer insulating film (not shown) such as a silicon oxide film is deposited by utilizing the CVD method or the like, the interlayer insulating film is subjected to the dry etching using the first contact etch stop layer 101 and the second contact etch stop layer 101 as the etch stop by using a mask pattern for the contact holes, thereby forming the SAC structure.

Here, in this embodiment, the first contact etch stop layer 101 for the N-channel MOSFET region is formerly formed. However, even when the second contact etch stop layer 102 for the P-channel MOSFET region is formerly formed, the same structure can be obtained, and the operation and effects in this case are the same as those of the former.

The fifth embodiment of the present invention has the following effects by addition of a few processes in addition to obtaining the same effects as those of the first and second embodiments in both the N-channel MOSFET region and the P-channel MOSFET region. That is to say, the formation of the first contact etch stop layer 101 and the second contact etch stop layer 102 which give the channel of the N-channel MOSFET region and the channel of the P-channel MOSFET region the tensile stress and the compressive stress, respectively, makes it possible to increase the drive current of both each of the first and second N-channel MOSFETs 203 and 204 and each of the first and second P-channel MOSFETs 205 and 206 independently of each other. In addition, the leaving of the third insulating film 9 in the gate region gap portions 8 of the N-channel MOSFET region and the P-channel MOSFET region through the etch back process makes it possible to increase both the electron mobility of each of the first and second N-channel MOSFETs 203 and 204, and the hole mobility of each of the first and second P-channel MOSFETs 205 and 206.

Therefore, even under the conditions in which it is difficult to enhance the performance by the future scaling, according to this embodiment of the present invention, it is possible to increase the drive current in the semiconductor device having the N-channel MOSFET region and the P-channel MOSFET region on the substrate.

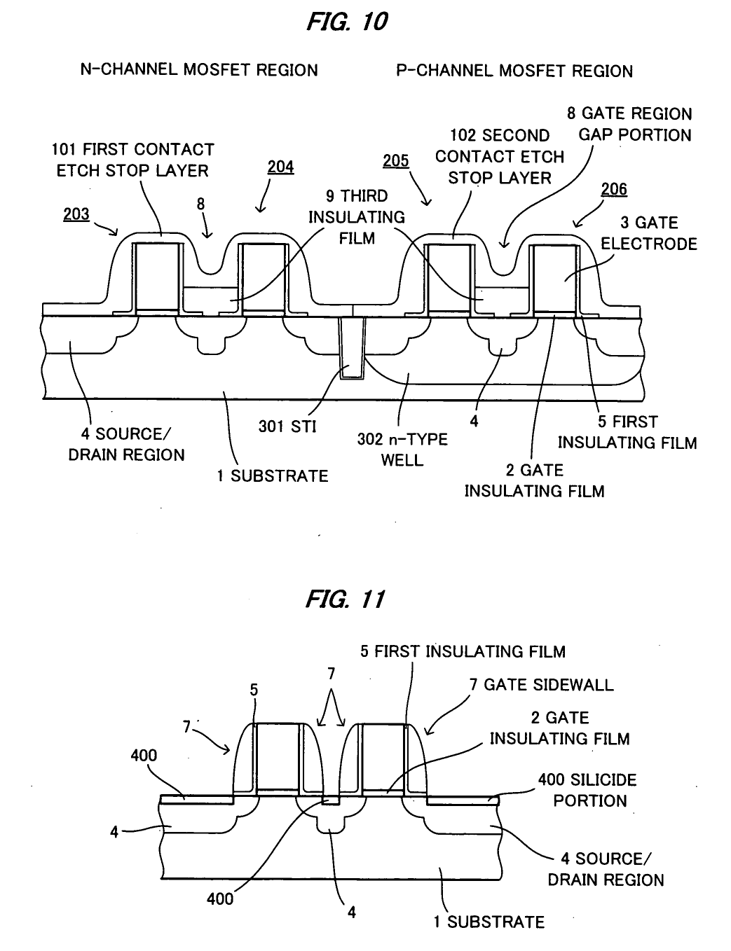

FIG. 10 is a cross sectional view showing a semiconductor device, in which each of gate sidewalls 7 is thinned, according to a sixth embodiment of the present invention. Before the third insulating film 9 is deposited on the gate region gap portion 8 defined between the first N-channel MOSFET 203 and the second N-channel MOSFET 204, and the gate region gap portion 8 defined between the first P-channel MOSFET 205 and the second P-channel MOSFET 206 in the process shown in FIG. 7A in the fifth embodiment, the second insulating films 6 of the gate sidewalls 7 including the first insulating films 5 and the second insulating films 6 are peeled off so that only the first insulating film 5 constitute the gate sidewalls 7. This process is carried out without any of hindrances because the contact regions have already been formed by utilizing the ion implantation method or the like and the source/drain regions 4 have already been formed so as to include the contact region and the extension regions. The fabricating processes in and after this process are the same as those of the fifth embodiment. In the semiconductor device according to this embodiment, L letter shaped and inverse L letter shaped first thin insulating films 5 are left on both sides of each of gate electrodes 3 so as to contact the both sides of each of the gate electrodes 3, and constitute the gate sidewalls 7, respectively.

Although in this embodiment, the second insulating film 6 is peeled off, and the L letter shaped and inverse L letter shaped first thin insulating films 5 are formed as the gate sidewalls 7, respectively, the present invention is not limited thereto. That is to say, when the gate sidewall portion for formation of the contact region by the ion implantation or the like is made of a single material, the gate sidewall portion can be processed to be thin by utilizing the suitable etching method or the like, thereby obtaining the same structure as that of this embodiment. In addition, the gate sidewall portion which is processed to be thin is not limited in structure to the L letter shape and inverse L letter shape, and thus fulfills the same function as that of the structure of this embodiment as long as it has a thin shape.

The sixth embodiment of the present invention has especially the following effects in addition to the effects of the fifth embodiment of the present invention. That is to say, the stress within the channel is induced by applying the film stress from the intermediate portion to the upper portion of the gate sidewall portion. In particular, since the gate sidewall portion has the thin shape, the tensile stress and the compressive stress which are given by the first contact etch stop layer 101 and the second contact etch stop layer 102, respectively, effectively act on the respective channels. Consequently, the formation of the first contact etch stop layer 101 and the second contact etch stop layer 102 which give the corresponding channels the tensile stress and the compressive stress, respectively, makes it possible to further increase the electron mobility of each of the first and second N-channel MOSFETs 203 and 204, and the hole mobility of each of the first and second P-channel MOSFETs 205 and 206, and increase the drive current of both each of the first and second N-channel MOSFETs 203 and 204, and each of the first and second P-channel MOSFETs 205 and 206.

In addition, the form in which the gate sidewall portion is thinned, and the contact etch stop layer is formed on the thin gate sidewall portion can be, of course, applied to the first to fourth embodiments, and its effects are also the same as those described above.

FIG. 11 is a cross sectional view explaining the effects of the first to sixth embodiments of the present invention. The reduction in contact resistance is given as one of the effects of the first to sixth embodiments. Normally, since the film in the narrow space defined between the gates becomes thick, the substrate is dug when the etch back is performed to remove the film remaining on the source/drain region 4. As a result, a silicide portion 400 is scraped, which causes an increase in contact resistance. However, according to the first to sixth embodiments, the film is left between the gates and the silicide portion 400 on the source/drain region 4 is not scraped. Consequently, the contact resistance is prevented from being increased, and thus the effect of enhancing the performance can be sufficiently obtained.

It should be noted that the present invention is not intended to be limited to the above-mentioned embodiments, and the various changes thereof can be implemented without departing from the gist of the invention. For example, in each of the above-mentioned embodiments, it has been described that the insulating film having the predetermined height is formed in the gate region gap portion defined between the adjacent two MOSFETs. However, the number of adjacent MOSFETs may be three or more, and the insulating film having the predetermined height may be formed in each of these gate region gap portions.

In addition, the constituent elements of the above-mentioned embodiments can be arbitrarily combined with one another without departing from the gist of the invention.

What is claimed is:

1. A semiconductor device, comprising:
two MOSFETs each comprising a gate electrode formed on a substrate through a gate insulating film, a gate sidewall formed on both sides of the gate electrode, and a source/drain region formed in the substrate;
a filled film filled between the adjacent gate sidewalls of the two MOSFETs; and
a covering layer covering the gate electrodes and the gate sidewalls of the two MOSFETs, and the filled film to give each of channels formed between the source/drain regions, respectively, a strain.

2. A semiconductor device according to claim 1, wherein:
the filled film comprises an insulating material.

3. A semiconductor device according to claim 2, wherein:
the insulating film comprises at least one of a silicon oxide and a silicon nitride.

4. A semiconductor device according to claim 1, wherein:
the covering layer comprises a silicon nitride.

5. A semiconductor device according to claim 1, wherein:
the two MOSFETs are N-channel MOSFETs, and the covering layer gives each of the channels the strain due to a tensile stress.

6. A semiconductor device according to claim 1, wherein:
the two MOSFETs are P-channel MOSFETs, and the covering layer gives each of the channels the strain due to a compressive stress.

7. A semiconductor device according to claim 1, wherein:
the gate sidewall is formed in L letter and inverse L letter shapes in a state in which a part of the gate sidewall contacts the gate electrode.

8. A semiconductor device, comprising:
two MOSFETs of a first conductivity type each comprising a first gate electrode formed on a substrate through a first gate insulating film, a first gate sidewall formed on both sides of the first gate electrode, and a first source/drain region formed in the substrate;
two MOSFETs of a second conductivity type each comprising a second gate electrode formed on a substrate through a second gate insulating film, a second gate sidewall formed on both sides of the second gate electrode, and a second source/drain region formed in the substrate;
a filled film filled between the adjacent first gate sidewalls of the two MOSFETs of the first conductivity type;
a first covering layer covering the first gate electrodes, the first gate sidewalls, and the filled film to give each of first channels formed between the first source/drain regions, respectively, a strain; and
a second covering layer covering the second gate electrodes and the second gate sidewalls to give each of second channels formed between the second source/drain regions, respectively, a strain.

9. A semiconductor device according to claim 8, wherein:
the second covering layer is a contact etch stop layer made of the same material as that of the filled film.

10. A semiconductor device according to claim 9, wherein:
the filled film comprises at least one of a silicon oxide and a silicon nitride.

11. A semiconductor device according to claim 10, wherein:
each of the first and second covering layers comprises a silicon nitride.

12. A semiconductor device according to claim 8, wherein:
each of the first and second gate sidewalls is formed in L lattice and inverse L letter shapes in a state in which at least parts of the first and second gate sidewalls contact the first and second gate electrodes, respectively.

13. A semiconductor device according to claim 8, wherein:
ones of the two MOSFETs of the first conductivity type, and the two MOSFETs of the second conductivity type are N-channel MOSFETs, and the others of the two MOSFETs of the first conductivity type, and the two MOSFETs of the second conductivity type comprise P-channel MOSFETs, respectively.

14. A semiconductor device according to claim 8, wherein:
the filled film is filled between the adjacent first gate sidewalls of the two MOSFETs of the first conductivity type, and between the adjacent two gate sidewalls of the two MOSFETs of the second conductivity type.

15. A semiconductor device according to claim 14, wherein:
the two MOSFETs of the first conductivity type are N-channel MOSFETs, and the first covering layer gives each of the first channels a tensile stress, and
the two MOSFETs of the second conductivity type are P-channel MOSFETs, and the second covering layer gives each of the second channels a compressive stress.

16. A method of fabricating a semiconductor device, comprising:
forming two MOSFETs each comprising a gate electrode formed on a substrate through a gate insulating film, a gate sidewall formed on both sides of the gate electrode, and a source/drain region formed in the substrate;
forming a filled film between the adjacent gate sidewalls of the two MOSFETs; and
covering the gate electrodes and the gate sidewalls of the two MOSFETs, and the filled film with a covering layer for giving each of channels of the source/drain regions a strain.

17. A method of fabricating a semiconductor device according to claim 16, wherein:
the filled film comprises at least one of a silicon oxide and a silicon nitride.

18. A method of fabricating a semiconductor device according to claim 16, wherein:
the covering layer comprises a silicon nitride.

19. A method of fabricating a semiconductor device according to claim 16, wherein:
the two MOSFETs are N-channel MOSFETs, and the covering layer gives each of the channels the strain due to a tensile stress.

20. A method of fabricating a semiconductor device according to claim 16, wherein:
the two MOSFETs are P-channel MOSFETs, and the covering layer gives each of the channels the strain due to a compressive stress.
